(19) United States
(12) Patent Application Publication
(10) Pub. No.: US 2026/0001429 A1
(43) Pub. Date: Jan. 1, 2026

(54) VEHICLE CHARGING SYSTEM FOR AN ELECTRIC VEHICLE HAVING ARC DETECTION

(71) Applicant: TE Connectivity Solutions GmbH, Schaffhausen (CH)

(72) Inventors: David Bruce Sarraf, Middletown, PA (US); Nathan Philip Myer, Middletown, PA (US); Robin Wesson, Middletown, PA (US); Paul Angell, Middletown, PA (US)

(21) Appl. No.: 18/976,542

(22) Filed: Dec. 11, 2024

Related U.S. Application Data
(60) Provisional application No. 63/665,372, filed on Jun. 28, 2024.

(51) Int. Cl. B60L 53/62; B60L 53/16; G01R 31/14

(52) U.S. Cl. CPC B60L 53/62; B60L 53/16; G01R 31/14

(57) ABSTRACT

A vehicle charging system for an electric vehicle includes a housing having a mating end for mating with a charging component and a charging terminal held by the housing connected to a power conductor to form a power transmission line. The vehicle charging system includes a charging controller for controlling vehicle charging along the power transmission line. The vehicle charging system includes a charging sensor assembly coupled to the charging controller monitoring charging status of the vehicle charging system and generating a charging output signal. The charging sensor assembly detects an arc signature from an arc event and generates an arc output signal. Based on the arc output signal, the charging controller generates a primary control output to perform a primary protective action including shutting down the charging operation and generates a secondary control output to perform a secondary protective action.

### CROSS REFERENCE TO RELATED APPLICATIONS

This application claims benefit to U.S. Application No. 63/665,372, filed 28 Jun. 2024, the subject matter of which is herein incorporated by reference in its entirety.

### BACKGROUND OF THE INVENTION

The subject matter herein relates generally to vehicle charging systems.

Electric vehicles (EV) and hybrid electric vehicles (HEV) include battery systems for operating the vehicles. The battery systems are charged by a vehicle charging system. For example, a charging connector, which is coupled to a power source, is connected to a charging inlet assembly of the vehicle to charge the battery. Known vehicle charging systems are not without disadvantages. For instance, the temperature of the terminals increase during charging, which may lead to damage to the charging components. In some instances, arcing may occur between the charging components, which can damage the charging connector and the charging inlet assembly.

A need remains for an arc detection method for a vehicle charging system of an electric vehicle.

### BRIEF DESCRIPTION OF THE INVENTION

In one embodiment, a vehicle charging system for an electric vehicle is provided and includes a housing having a mating end for mating with a charging component for the electric vehicle. The housing includes an internal cavity. The vehicle charging system includes a charging terminal held by the housing in the internal cavity. The charging terminal includes a mating end for mating with the charging component. The charging terminal is connected to a power conductor to form a power transmission line. The vehicle charging system includes a charging controller for controlling vehicle charging along the power transmission line. The charging controller includes a charging sensor assembly coupled to the charging controller. The charging sensor assembly monitors charging status of the vehicle charging system along the power transmission line and generates a charging output signal. The charging sensor assembly transmits the charging output signal to the charging controller. The charging sensor assembly is configured to detect an arc signature from an arc event and generate an arc output signal to the charging controller. Based on the arc output signal associated with the arc event, the charging controller generates a primary control output to perform a primary protective action including shutting down the charging operation. Based on the arc output signal associated with the arc event. The charging controller generates a secondary control output to perform a secondary protective action.

In another embodiment, a method of operating a vehicle charging system includes a housing having a mating end for mating with a charging component for the electric vehicle and a charging terminal held by the housing includes a mating end for mating with the charging component and is connected to a power conductor to form a power transmission line. The vehicle charging system includes a charging controller for controlling vehicle charging along the power transmission line. The charging controller includes a charging sensor assembly coupled to the charging controller. The method monitors charging status of the vehicle charging system along the power transmission line with the charging sensor assembly. The method generates a charging output signal at the charging sensor assembly and transmits the charging output signal to the charging controller. The method detects an arc signature from an arc event along the power transmission line with the charging sensor assembly. The method generates an arc output signal at the charging sensor assembly and transmits the arc output signal to the charging controller and generates a primary control output at the charging controller based on the arc output signal associated with the arc event to perform a primary protective action includes shutting down the charging operation. The method generates a secondary control output at the charging controller based on the arc output signal associated with the arc event to perform a secondary protective action.

### BRIEF DESCRIPTION OF THE DRAWINGS

FIG. 1 is a schematic view of a vehicle charging system in accordance with an exemplary embodiment.

FIG. 2 is a front perspective view of a charging component in accordance with an exemplary embodiment.

FIG. 3 is a rear perspective view of the charging component in accordance with an exemplary embodiment.

FIG. 4 is a perspective view of the charging controller in accordance with an exemplary embodiment.

FIG. 5 is a cross-sectional view of the charging component in accordance with an exemplary embodiment showing a second charging component coupled to the charging component.

FIG. 6 is a cross sectional view of the charging component in accordance with an exemplary embodiment showing the second charging component coupled to the charging component.

### DETAILED DESCRIPTION OF THE INVENTION

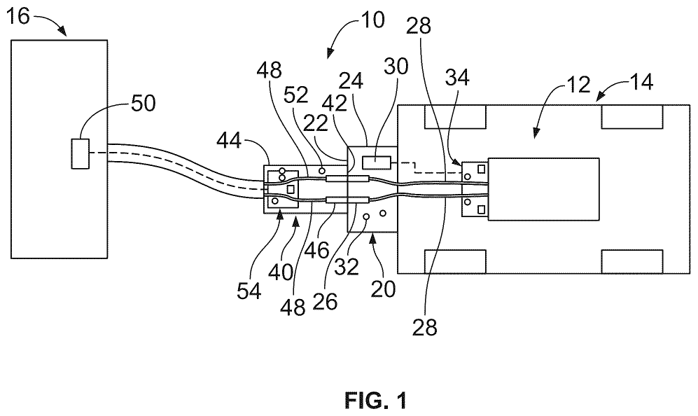

FIG. 1 is a schematic view of a vehicle charging system 10 in accordance with an exemplary embodiment. The vehicle charging system 10 is used for charging a battery system 12 of a vehicle 14, such as an electric vehicle or a hybrid electric vehicle. The vehicle charging system 10 includes a first charging component 20 and a second charging component 40. The first and second charging components 20, 40 are coupled together to charge the battery system 12 of the vehicle 14. In an exemplary embodiment, the first charging component 20 is coupled to the vehicle 14 and the second charging component 40 is coupled to a power supply 16 used for charging the battery system 12 of the vehicle 14. For example, the first charging component 20 may be a charging inlet assembly 22 mounted to the vehicle 14 and the second charging component 40 may be a charging connector 42 (for example, charging plug) which may be provided at a charging station or coupled to the building wiring of the home or building where the vehicle 14 is parked.

The first charging component 20 includes a housing 24 holding a plurality of charging terminals 26 and power conductors 28 coupled to the charging terminals 26. The charging terminals 26 may be DC charging terminals and/or AC charging terminals. The power conductors 28 may be power cables, busbars, or other types of conductors.

The first charging component 20 includes a charging controller 30, which may be used to control vehicle charging. For example, the charging controller 30 may control power supply along the charging terminals 26. The charging controller 30 may communicate with the second charging component 40, such as to control the second charging component 40. For example, the charging controller 30 may cause the second charging component 40 to turn on the power supply, turn off the power supply, increase power supply, and/or decrease power supply.

In an exemplary embodiment, the first charging component 20 includes a temperature sensor 32 operably coupled to the charging controller 30 to monitor a temperature of the charging terminals 26. The vehicle charging may be controlled based on the temperature readings of the temperature sensor 32. The temperature sensor 32 may be used for arc detection, such as by monitoring for a spike in temperature or a temperature above a threshold temperature, which may be higher than a normal operating temperature range.

In an exemplary embodiment, the first charging component 20 includes a charging sensor assembly 34 coupled to the charging controller 30. The charging sensor assembly 34 monitors charging status of the vehicle charging system along the power transmission lines and generating a charging output signal. The charging sensor assembly 34 transmits the charging output signal to the charging controller 30. The charging sensor assembly 34 is configured to detect an arc signature from an arc event and generate an arc output signal to the charging controller 30. In an exemplary embodiment, based on the arc output signal associated with the arc event, the charging controller 30 generates a primary control output to perform a primary protective action including shutting down the charging operation. In an exemplary embodiment, based on the arc output signal associated with the arc event, the charging controller 30 generates a secondary control output to perform a secondary protective action.

In an exemplary embodiment, the charging sensor assembly 34 includes one or more sensors monitoring the charging status. For example, the charging sensor assembly 34 may include one or more temperature sensors, such as the temperature sensor 32. The charging sensor assembly 34 may include one or more optical sensors, such as a light detector, configured to detect light output from the arc event. The charging sensor assembly 34 may include one or more sensor antenna for detecting electromagnetic fields of signals transmitted along the power transmission lines, which can be used to detect an arc signature during the arc event. The charging sensor assembly 34 may include one or more current sensors, such as current transformers, operably coupled to the charging controller 30 to monitor current transmitted along the power transmission lines within the first charging component 20, such as at the charging terminal 26 and/or along the power conductors 28.

The charging sensor assembly 34 is operably coupled to the charging controller 30 to control the vehicle charging, such as based on the monitored signals and/or based on detection of an arc event by the charging sensor assembly 34. For example, when the arc event is detected, the primary protective action taken by the charging controller 30 is to immediately shut off the power supply to stop the charging process and extinguish the arc. For example, the charging controller 30 may be operably coupled to a charging disconnecting device, such as a pyrofuse, a contactor, or a solid state relay configured to stop charging current on the power transmission line. The primary control output is transmitted to the charging disconnecting device to shut down the charging operation. In an exemplary embodiment, the charging controller 30 may communicate with the second charging component 40, such as to shut off the power supply to stop the charging process. Such redundant action allows both charging components to shut down the charging operation as a primary protective action.

In an exemplary embodiment, when the arc event is detected, one or more secondary protective actions are taken by the charging controller. For example, The secondary control output may include logging the arc event in a database. The database may be on the vehicle, at the charging station, a cloud-type server or database, and the like. The system may track the component life and system behavior over a network of infrastructure components based on the database(s). Logging the arc event may include sending arcing information to the database. For example, the arcing information may be the arc output signal from the arc sensor assembly, such as the sensor readings, the time the arc event occurred, any actions taken by the system based on the arc event, and the like. The system may identify the charging components for further inspection or replacement based on the logged arc event. The system may identify further actions that may be taken based on the logged arc event, which may be dependent on the severity of the arc event.

The secondary control output may include sending the secondary control output to the charging component 40 to control the charging operation of the charging component 40. For example, control signals may be transmitted between the vehicle and the charging station to control operation of one or both of the charging components upon the detection of the arc event.

The secondary control output may include transmitting a warning signal to the operator of the vehicle. The warning signal may be at least one of a visible signal, an audible signal, a tactile signal, and an olfactory signal. The warning signal may be transmitted to the operator of the vehicle to warn the operator to exit the vehicle and inspect the components for damage or potential fire.

The charging sensor assembly 34 (and/or components of the charging sensor assembly 34) may be provided at various locations within the vehicle charging system 10. For example, the charging sensor assembly 34 may be located in or on the first charging component 20. In other various embodiments, the charging sensor assembly 34 may be located in or on the vehicle 14, such as in or on the battery system 12. For example, the charging sensor assembly 34 may be incorporated in a battery distribution unit (BDU) or other component of the battery system 12.

The second charging component 40 includes a housing 44 holding a plurality of charging terminals 46 and power conductors 48 coupled to the charging terminals 26. The charging terminals 46 are configured to be mated with the charging terminals 26. In various embodiments, the charging terminals 46 are socket terminals and the charging terminals 26 are pin terminals; however, other types of terminals may be used in alternative embodiments. The charging terminals 46 may be DC charging terminals and or AC charging terminals. The power conductors 48 may be power cables, busbars, or other types of conductors.

The second charging component 40 includes a charging controller 50, which may be used to control vehicle charging. For example, the charging controller 50 may control power supply along the charging terminals 46. The charging controller 50 may communicate with the first charging component 20. The charging controller 50 may turn on the power supply, turn off the power supply, increase the power supply, and/or decrease the power supply. The charging controller 50 may control the voltage and/or current supplied by the second charging component 40.

In an exemplary embodiment, the second charging component 40 includes a temperature sensor 52 operably coupled to the charging controller 50 to monitor a temperature of the charging terminals 46. The vehicle charging may be controlled based on the temperature readings of the temperature sensor 52. The temperature sensor 52 may be used for arc detection, such as by monitoring for a spike in temperature or a temperature above a threshold temperature, which may be higher than a normal operating temperature range.

In an exemplary embodiment, the second charging component 40 includes a charging sensor assembly 54 coupled to the charging controller 50. The charging sensor assembly 54 monitors charging status of the vehicle charging system (for example, of the charging plug and/or the charging station) along the power transmission lines and generating a charging output signal. The charging sensor assembly 54 transmits the charging output signal to the charging controller 50. The charging sensor assembly 54 is configured to detect an arc signature from an arc event and generate an arc output signal to the charging controller 50. In an exemplary embodiment, based on the arc output signal associated with the arc event, the charging controller 50 generates a primary control output to perform a primary protective action including shutting down the charging operation. In an exemplary embodiment, based on the arc output signal associated with the arc event, the charging controller 50 generates a secondary control output to perform a secondary protective action.

In an exemplary embodiment, the charging sensor assembly 54 includes one or more sensors monitoring the charging status. For example, the charging sensor assembly 54 may include one or more temperature sensors, such as the temperature sensor 52. The charging sensor assembly 54 may include one or more optical sensors, such as a light detector, configured to detect light output from the arc event. The charging sensor assembly 54 may include one or more sensor antenna for detecting electromagnetic fields of signals transmitted along the power transmission lines, which can be used to detect an arc signature during the arc event. The charging sensor assembly 54 may include one or more current sensors, such as current transformers, operably coupled to the charging controller 50 to monitor current transmitted along the power transmission lines within the second charging component 40, such as at the charging terminal 46 and/or along the power conductors 48.

The charging sensor assembly 54 is operably coupled to the charging controller 50 to control the vehicle charging, such as based on the monitored signals and/or based on detection of an arc event by the charging sensor assembly 54. For example, when the arc event is detected, the primary protective action taken by the charging controller 50 is to immediately shut off the power supply to stop the charging process and extinguish the arc. For example, the charging controller 50 may be operably coupled to a charging disconnecting device, such as a pyrofuse, a contactor, or a solid state relay configured to stop charging current on the power transmission line. The primary control output is transmitted to the charging disconnecting device to shut down the charging operation. In an exemplary embodiment, the charging controller 50 may communicate with the first charging component 20, such as to shut off the power supply to stop the charging process. Such redundant action allows both charging components to shut down the charging operation as a primary protective action.

In an exemplary embodiment, when the arc event is detected, one or more secondary protective actions are taken by the charging controller. For example, The secondary control output may include logging the arc event in a database. The database may be on the vehicle, at the charging station, a cloud-type server or database, and the like. The system may track the component life and system behavior over a network of infrastructure components based on the database(s). Logging the arc event may include sending arcing information to the database. For example, the arcing information may be the arc output signal from the arc sensor assembly, such as the sensor readings, the time the arc event occurred, any actions taken by the system based on the arc event, and the like. The system may identify the charging components for further inspection or replacement based on the logged arc event. The system may identify further actions that may be taken based on the logged arc event, which may be dependent on the severity of the arc event.

The secondary control output may include sending the secondary control output to the charging component 40 to control the charging operation of the charging component 40. For example, control signals may be transmitted between the vehicle and the charging station to control operation of one or both of the charging components upon the detection of the arc event.

The secondary control output may include transmitting a warning signal to the operator of the vehicle. The warning signal may be at least one of a visible signal, an audible signal, a tactile signal, and an olfactory signal. The warning signal may be transmitted to the operator of the vehicle to warn the operator to exit the vehicle and inspect the components for damage or potential fire.

The charging sensor assembly 54 (and/or components of the charging sensor assembly 54) may be provided at various locations within the vehicle charging system 10. For example, the charging sensor assembly 54 may be located in or on the second charging component 40. For example, the charging sensor assembly 54 may be located in or on the charging plug. In other various embodiments, the charging sensor assembly 54 may be located in or on the power supply 16, such as in or on the charging station.

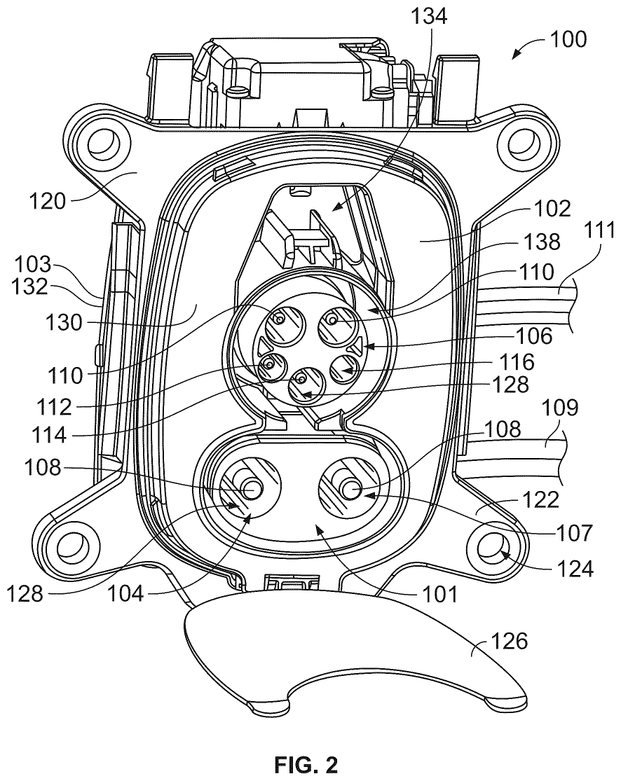

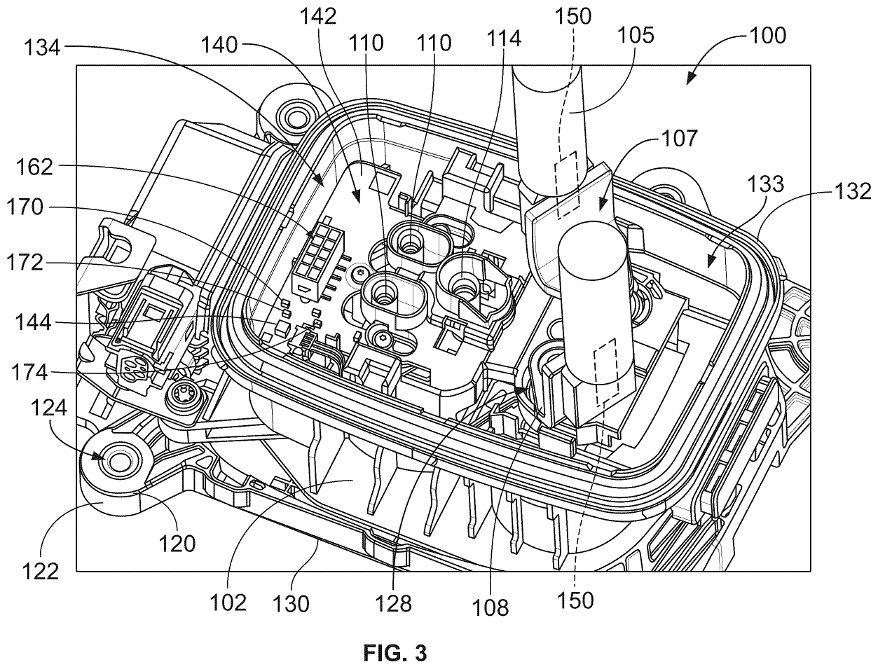

FIG. 2 is a front perspective view of a charging component 100 in accordance with an exemplary embodiment. FIG. 3 is a rear perspective view of the charging component 100 in accordance with an exemplary embodiment. In the illustrated embodiment, the charging component 100 is a charging inlet assembly and may be referred to hereinafter as a charging inlet assembly 100. The charging inlet assembly 100 is configured to be mated with a complimentary charging component (not shown), such as a charging connector or plug charger.

The charging inlet assembly 100 defines a power connector 101 configured to be electrically connected to the charging connector for charging a battery system of a vehicle, such as an electric vehicle (EV) or hybrid electric vehicle (HEV). In an exemplary embodiment, the charging inlet assembly 100 is configured for mating with a DC fast charging connector, such as the SAE combo CCS charging connector or the NACS charging connector, in addition to AC charging connectors, such as the SAE J1772 charging connector. In various embodiments, the charging inlet assembly 100 has a CCS1 (5 pin) AC configuration. In other various embodiments, the charging inlet assembly 100 may have a CCS2 (7 pin) AC configuration. Other standard inlet configurations may be used in alternative embodiments, such as the NACS configuration.

The charging inlet assembly 100 includes a housing 102 configured to be mounted in the vehicle. The housing 102 forms a portion of the power connector 101 for mating with the charging connector. A rear cover 103 (shown in FIG. 2 but removed in FIG. 3 to illustrate components of the charging inlet assembly 100) is coupled to a rear of the housing 102 to close out the housing 102 and the internal components of the charging inlet assembly 100. The rear cover 103 may be sealed to the housing 102 to prevent moisture and debris from entering the internal compartment of the housing 102. In an exemplary embodiment, the power connector 101 defines a DC charging portion 104 and an AC charging portion 106. The charging portions 104, 106 may form receptacles or openings that receive a plug of the charging connector. The charging inlet assembly 100 includes a plurality of charging terminals 107 for connection to the charging connector. Power conductors 105 are electrically connected to the charging terminals 107 and routed within the vehicle, such as to the battery. The power conductors 105 may be power cables, busbars, or other types of conductors. The charging terminals 107 and the power conductors 105 form power transmission lines through the vehicle.

The DC charging portion 104 is configured for mating with a DC charging connector or a DC section of the charging connector. The DC charging portion may be used for fast charging. In an exemplary embodiment, the charging terminals 107 of the charging inlet assembly 100 include DC charging terminals 108 at the DC charging portion 104, such as a pair of the DC charging terminals 108. The DC charging terminals 108 are configured to be electrically connected to the DC charging connector. The charging inlet assembly 100 includes DC power conductors 109 (FIG. 2) electrically connected to the DC charging terminals 108. The DC power conductors 109 may be terminated directly to the DC charging terminals 108, such as being crimped or welded to the DC charging terminals 108. In other embodiments, the DC power conductors 109 may be electrically connected to the DC charging terminals 108 through a separable interface, such as through connectors mated to the housing 102 at the rear. The DC charging terminals 108 and the DC power conductors 109 form power transmission lines through the vehicle.

The AC charging portion 106 is configured for mating with an AC charging connector or an AC section of the charging connector. In an exemplary embodiment, the charging terminals 107 of the charging inlet assembly 100 includes AC power terminals 110 at the AC charging portion 106, such as a pair of the AC power terminals 110. The charging terminals 107 of the charging inlet assembly 100 include a proximity terminal 112 at the AC charging portion 106. The charging terminals 107 of the charging inlet assembly 100 include a ground terminal 114 at the AC charging portion 106. The charging terminals 107 of the charging inlet assembly 100 include a communication terminal 116 at the AC charging portion 106. The AC power terminals 110, the proximity terminal 112, the ground terminal 114, and the communication terminal 116 are configured to be electrically connected to the AC charging connector.

The charging inlet assembly 100 includes AC conductors 111 (FIG. 2) electrically connected to the corresponding AC terminals 110, 112, 114, 116. The AC conductors 111 may be terminated directly to the AC terminals 110, 112, 114, 116, such as being crimped or welded thereto. In other embodiments, the AC conductors 111 may be electrically connected to the AC terminals 110, 112, 114, 116 through a separable interface, such as through connectors mated to the housing 102 at the rear. The AC charging terminals 110 and the AC power conductors 111 form power transmission lines through the vehicle.

The conductors 109, 111 extend from the charging inlet assembly 100 to another component of the vehicle, such as the battery system of the vehicle. The conductors 109, 111 transmit power, such as to the battery of the vehicle. The DC power conductors 109 may transmit high voltage for charging the battery and the AC conductors 111 may transmit low voltage for charging the battery. Optionally, one or more of the conductors 111 may be electrically connected to a battery control unit (not shown) of the battery system, such as to transmit data between the charging inlet assembly 100 and the battery system, such as data relating to the charging operation. For example, the conductor 111 may transmit data relating to charging start/stop, operating temperature of the power terminals 108 and/or 110, or other charging data. The conductor 111 may send a proximity signal to the battery system indicating when the charging device is mated to the power connector 101 of the charging inlet assembly 100.

The charging inlet assembly 100 includes a mounting flange 120 (FIG. 1) coupled to the housing 102. The mounting flange 120 is used to couple the charging inlet assembly 100 to the vehicle. The mounting flange 120 includes mounting tabs 122 having openings 124 that receive fasteners (not shown) used to secure the charging inlet assembly 100 to the vehicle. Other types of mounting features may be used to secure the charging inlet assembly 100 to the vehicle. The mounting flange 120 may include a seal to seal the charging inlet assembly 100 to the vehicle.

In an exemplary embodiment, the charging inlet assembly 100 includes a terminal cover 126 (FIG. 2) at a front 130 of the housing 102. The terminal cover 126 is hingedly coupled to the mounting flange 120 and/or the housing 102. The terminal cover 126 is used to cover portions of the housing 102, such as the power connector 101. The terminal cover 126 may be used to cover the DC charging terminals 108 and/or the AC power terminals 110, which are located in corresponding terminal channels 128 in the housing 102.

The rear cover 103 is provided at a rear 132 of the housing 102 to close access to a rear chamber 133 at the rear 132 of the housing 102. The rear cover 103 may be clipped or latched onto the main part of the housing 102, such as using clips or latches. Other types of securing features, such as fasteners may be used in alternative embodiments. A perimeter seal may be provided between the rear cover 103 and the housing 102.

In an exemplary embodiment, the housing 102 of the charging inlet assembly 100 includes an internal cavity 134 that receives the components of the charging inlet assembly 100. The rear chamber 133 is at the rear of the internal cavity 134. The internal cavity 134 includes the terminal channels 128 that receive the corresponding charging terminals 107. The terminal channels 128 may be separated from each other and other components by walls of the housing 102. The internal cavity 134 includes a front chamber 138 at the front that receives the charging connector.

In an exemplary embodiment, the charging inlet assembly 100 includes a charging controller 140 for controlling charging of the vehicle through the charging inlet assembly 100. The charging controller 140 may be received in the internal cavity 134, such as in the rear chamber 133. The charging controller 140 may be communicatively coupled to the other charging component, such as the charging connector or plug, to control the charging activity or to another charging controller (for example, within the battery distribution unit) within the vehicle for controlling the charging process. The charging controller 140 may be communicatively coupled to the charging connector through one or more of the terminals 107. The charging controller 140 may turn on the power supply, turn off the power supply, increase the power supply, and/or decrease the power supply. The charging controller 140 may be located remote from the housing 102, such as at the battery control module of the vehicle charging system.

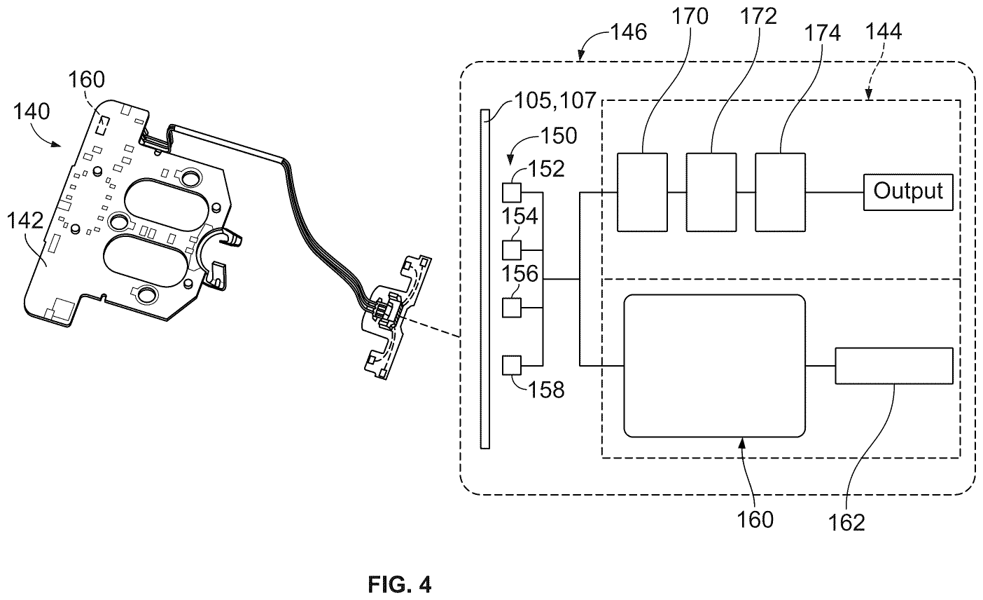

With additional reference to FIG. 4, which is a perspective view of the charging controller 140 in accordance with an exemplary embodiment, the charging controller 140 includes a circuit board 142, a control device 144, and other various components and circuitry to control operation of the charging inlet assembly 100. The control device 144 may be a processor or microcontroller. The control device 144 may include a multi-pin connector coupled to the circuit board 142.

In an exemplary embodiment, the control assembly includes a charging sensor assembly 146 having one or more sensors 150 used for monitoring the charging process to control the charging operation. The sensors 150 are used to sense operating characteristics of the components or the charging process to control charging. The sensors 150 are connected to the charging controller 140, such as being connected to the circuit board 142 by a wire or connector.

In various embodiments, the sensors 150 include temperature sensors 152. The temperature sensors 152 monitor operating temperatures of the DC charging terminals 108. The charging operation may be controlled based on the operating temperatures of the DC charging terminals 108. For example, as the temperature increases or approaches an allowable operating temperature, the power supply may be decreased. For example, the voltage or current may be reduced. The charging operation may stop if the operating temperature of the DC charging terminals 108 is above a threshold temperature. The temperature sensor 152 may be used for arc detection, such as by monitoring for a spike in temperature or a temperature above a threshold temperature, which may be higher than a normal operating temperature range.

In various embodiments, the sensors 150 include current sensors 154. The current sensors 154 monitor the current of the power transmission line(s) (for example, the charging terminals 107 and the power conductors 105). In an exemplary embodiment, the current sensor 154 includes a current transformer or other current measuring device that measures the current of the power transmission line. The current transformer includes a primary coil that carries the current to be measured, and a secondary coil that produces a current proportional to the primary coil that is sent to a meter (for example, a voltmeter) or other instrument for measurement. However, other types of current sensors may be used in alternative embodiments, such as a Hall effect sensor. The Hall effect sensor may sense current at a frequency range similar to the frequency range on the power transmission line during an arc event (for example, having a sensing range similar to an arc signature).

In various embodiments, the sensors 150 include one or more optical sensors 156 configured to detect light output from the arc event. The optical sensor 156 may include a light detector, such as a photodiode, to detect light from the arc event. For example, light is generated by the arc event, such as in the optical frequency range. The light of the electrical arcing may be in a predetermined range, such as infrared frequency range and/or visible frequency range and/or ultraviolet frequency range. The light detector is positioned to visibly monitor the internal cavity 134, such as in the terminal channel 128, to detect the arc event in the vicinity of the mating interface between the charging terminals 107.

The sensors 150 may include one or more sensor antenna 158 for detecting electromagnetic fields of signals transmitted along the power transmission lines, which can be used to detect an arc signature during the arc event. The sensor antenna elements may be located proximate to the power transmission line(s) and are connected to one or more antenna circuits processing signals from the antenna elements. In an exemplary embodiment, the antenna elements may include e-field antenna elements and/or b-field antenna elements and/or h-field antenna elements. The antenna elements may measure electrostatic signals. The antenna elements may measure magnetic signals. Other types of antenna elements may be used in alternative embodiments.

The sensors 150 of the charging sensor assembly 146 are coupled to the charging controller 140. For example, the charging sensor assembly 146 may transmit one or more outputs to the charging controller 140, such as relating to the charging operation and/or arc events. For example, the charging sensor assembly 146 may transmit a charging output signal relating to the charging process, such as a temperature of the terminals, the current transmitted along the power transmission lines, and the like. The charging sensor assembly 146 may transmit an arc output signal relating to detection of an arc event. The charging controller 140 may include processing devices, such as a microcontroller, a processor, a digital signal processor, a neural network, frequency diplexers, and the like, to process the signals. The charging controller 140 is used to control the charging operation. For example, the charging controller 140 may turn on the power supply, turn off the power supply, increase the power supply, and/or decrease the power supply based on the signals from the charging sensor assembly 146 (for example, based on the current output signal and/or based on the arc output signal).

In an exemplary embodiment, the charging sensor assembly 146 is used to detect an arc signature relating to an arc event within the charging inlet assembly 100, such as at mating ends of the charging terminals 107. For example, when one or more of the sensors 150 senses an arc event (for example, high current, light, high frequency, high temperature, and the like) the charging sensor assembly 146 outputs the arc output signal to the charging controller 140. The arc output signal is transmitted to the charging controller 140 to control the charging operation based on the detection of the arc event.

In an exemplary embodiment, based on the arc output signal associated with the arc event, the charging controller 140 generates a primary control output to perform a primary protective action including shutting down the charging operation. In an exemplary embodiment, based on the arc output signal associated with the arc event, the charging controller 140 generates a secondary control output to perform a secondary protective action. Different process flows and protective actions can be taken depending on the severity of the arc, which can be determined by the intensity of the signal picked up by the sensor(s) 150. For example, when arcing occurs during lower power charging, slower methods of interrupting the current might be reasonable. When arcing occurs during high power charging faster methods of interrupting the current might be necessary.

The charging sensor assembly 146 is operably coupled to the charging controller 140 to control the vehicle charging, such as based on the monitored signals and/or based on detection of an arc event by the charging sensor assembly 146. For example, when the arc event is detected, the primary protective action taken by the charging controller 140 is to immediately shut off the power supply to stop the charging process and extinguish the arc. The current and voltage from the charging connector is stopped immediately to prevent damage to the components or the vehicle. In an exemplary embodiment, the charging controller 140 is operably coupled to a charging disconnecting device 160, such as a pyrofuse, a contactor, or a solid state relay configured to stop charging current on the power transmission line. The pyrofuse is fast reacting to shut off the current flow. The mechanical contactor is slower, but is reusable. The solid state relay is quick reacting to shut off the current flow and is reusable. The primary control output is transmitted to the charging disconnecting device 160 to shut down the charging operation.

In an exemplary embodiment, the charging controller 140 includes a communication module 162 to allow communication with other components, such as within the vehicle and/or at the charging station. The communication module 162 may be a wireless communication module. In other various embodiments, the communication module 162 may be a wired communication device. The communication module 162 may communicate with the charging station through communication terminals, such as the pilot and proximity pins. The communication module 162 allows communication with the second charging component (for example, the charging plug and/or the charging station) to shut off the power supply to stop the charging process. Such redundant action allows both charging components to shut down the charging operation as a primary protective action. A cooperative current shut down process may be achieved by communicating a signal relating to the arc event to both components of the charging system to improve reliability of arc detection and redundancy against failure. Both systems may operate independently based on data or signals shared between the components during the charging process, such as relating to arc events.

In an exemplary embodiment, when the arc event is detected, one or more secondary protective actions are taken by the charging controller 140. For example, the secondary control output may include logging the arc event in a database. The database may be on the vehicle, at the charging station, a cloud-type server or database, and the like. The system may track the component life and system behavior over a network of infrastructure components based on the database(s). Logging the arc event may include sending arcing information to the database. For example, the arcing information may be the arc output signal from the arc sensor assembly 146, such as the sensor readings, the time the arc event occurred, any actions taken by the system based on the arc event, and the like. The system may identify or flag the charging components for further inspection or replacement based on the logged arc event. The system may identify further actions that may be taken based on the logged arc event, which may be dependent on the severity of the arc event.

The secondary control output may include sending the secondary control output to the other charging component (for example, the charging plug and/or the charging station) to control the charging operation of the charging component. For example, control signals may be transmitted between the vehicle and the charging station to control operation of one or both of the charging components upon the detection of the arc event.

The secondary control output may include transmitting a warning signal to the operator of the vehicle. The warning signal may be at least one of a visible signal, an audible signal, a tactile signal, and an olfactory signal. The warning signal may be transmitted by the communication module 162. The warning signal may be transmitted to the operator of the vehicle to warn the operator to exit the vehicle and inspect the components for damage or potential fire.

In an exemplary embodiment, the charging controller 140 includes the control device 144 to control one or more functions of the vehicle charging system. The control device 144 may include software and/or hardware for processing the signals to control the charging operation. The control device 144 may receive signals and/or inputs, such as from the charging sensor assembly 146. The control device 144 may process and/or analyze the signals/inputs to determine and/or generate one or more outputs, such as the primary control output and/or the secondary control output.

In an exemplary embodiment, the control device 144 or other component of the charging controller 140 includes an envelope detector 170 defining a signal envelope encompassing the arc signature. The envelope detector 170 detects the arc event when the arc signature is in the signal envelope. The envelope detector 170 may include a series of amplifiers to limit the incoming signal bandwidth to the region typically associated with arcing (for example, between 300 kHz-3 MHz), then apply a threshold detector to sense the presence/absence of the signal. The envelope detector 170 may include one or more filters, such as a low pass filter and/or a high pass filter.

In an exemplary embodiment, the control device 144 or other component of the charging controller 140 includes an anomaly detector 172 configured to detect anomalous sensor readings from the arc sensor assembly 146. For example, during an arc event, the sensor readings from one or more of the sensors 150 may be affected leading to anomalous sensor readings. For example, the temperature sensor may read a negative temperature. Rather than discarding or rejecting such anomalous sensor readings as being untrustworthy, the anomaly detector 172 treats the anomalous sensor readings as a positive arc signature for the charging controller 140. The charging controller 140 may generate the primary control output and the secondary control output based on the anomalous sensor readings.

In an exemplary embodiment, the control device 144 or other component of the charging controller 140 includes a digital signal processor 174 configured to process the arc output signal. The digital signal processor 174 is configured to analyze the arc output signal to determine when the arc event is occurring. The digital signal processor 174 is configured to generate the primary control output and the secondary control output based on the processed arc output signal. The digital signal processor 174 provides digital equivalent signals that are sampled and digitized the operated on numerically to provide functions such as filtering, detection, spectrograms, and the like. The digital signal processor 174 uses algorithms to process the signals. The algorithms are immune from drift and component tolerance variations. The parameters of the algorithms can be changed dynamically under digital control. In the case of arc detection, key parameters such as the detection algorithm or key parameters such as filter bandpass can be changed dynamically as needed to suit a particular phase of the charging cycle. The control device or other component of the charging controller 140 may include a neural network or artificial intelligence structure to serve as an envelope detector, anomaly detector, sensor fusion device to combine signals from multiple sensors and produce an arc/no-arc output decision. The neural network could improve detection quality by improving rates of detection, false positives, and false negatives, as well as fusing data from multiple sensors and inputs as a diversity strategy.

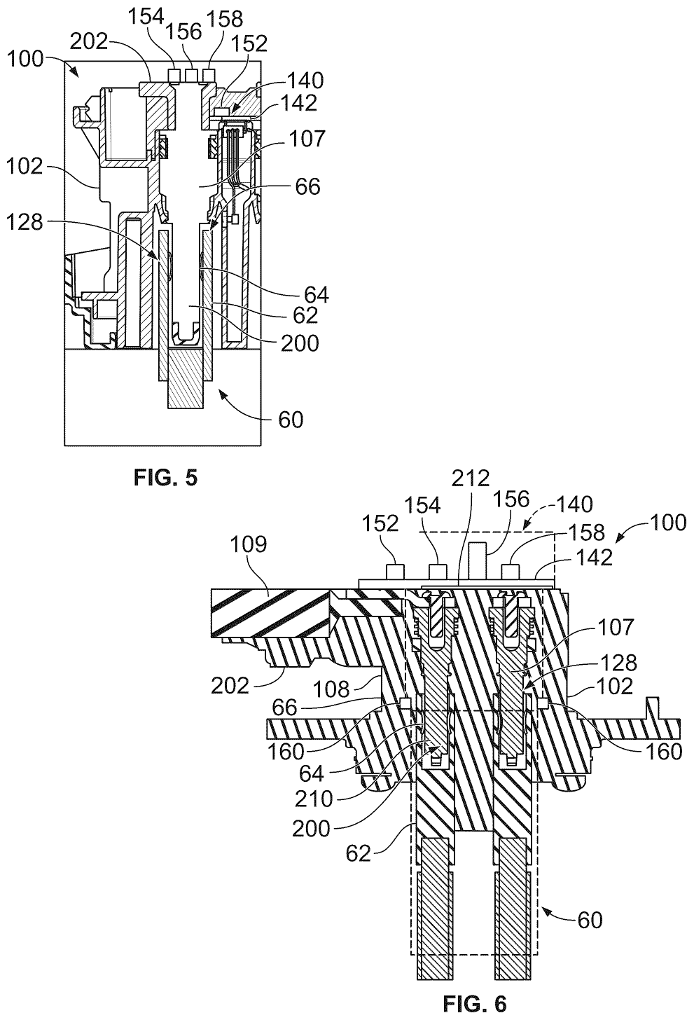

FIG. 5 is a cross-sectional view of the charging component 100 in accordance with an exemplary embodiment showing a second charging component 60 coupled to the charging component. FIG. 6 is a cross sectional view of the charging component 100 in accordance with an exemplary embodiment showing the second charging component 60 coupled to the charging component. In the illustrated embodiment, the charging component 100 is the charging inlet assembly. The second charging component 60 is a charging connector such as a plug charger.

The charging terminals 107 are shown in the terminal channels 128 of the housing 102. The charging terminals 107 are mated with charging terminals 62 of the charging connector 60. In the illustrated embodiment, the charging terminals 107 are pin terminals and the charging terminals 62 are socket terminals having spring contacts 64 in the sockets configured to electrically connect the charging terminals 62 and the charging terminals 107. The spring contacts 64 form a compliant, separable interface. The spring contacts 64 may be susceptible to failure due to overheating, and the failure may lead to an electrical arc event. The temperature sensors 152 monitor temperature of the charging terminals 107. The current sensors 154 monitor the current transmitted along the power transmission line (for example, along the charging terminal 107). In an exemplary embodiment, the current sensors 154 monitor the current on the power transmission line for arc events, such as at mating ends 66 of the charging terminals 62 or mating ends of the charging terminals 107. The optical sensor 156 monitors from the arc event in the vicinity of the mating interfaces between the charging terminals 62, 107. The sensor antenna 158 monitors electromagnetic fields along the power transmission lines.

The charging terminal 107 includes a mating pin 200 at a mating end 210 of the charging terminal 107 and a cable connector 202 at a rear 212 of the charging terminal 107. The charging terminal 107 extends along a longitudinal axis. The mating pin 200 is configured to be mated to the spring contact 64 of the charging terminal 62 of the charging connector 60. The cable connector 202 is configured to be electrically connected to the power conductor 109. In various embodiments, the cable connector 202 is configured to be terminated to the power conductor 109 by crimping to the power conductor 109. In other various embodiments, the cable connector 202 is terminated to the power conductor 109 by other processes, such as being welded to a weld tab at the rear end of the charging terminal 107. The conductor 109 may extend from the charging terminal 107 perpendicular to the longitudinal axis. Alternatively, the conductor 109 may extend from the charging terminal 107 parallel to the longitudinal axis.

In an exemplary embodiment, the temperature sensor 152 is coupled to the charging terminal 107 at the rear of the charging terminal 107, such as at the cable connector 202. The charging terminal 107 is both electrically conductive and thermally conductive. As the mating pin 200 heats up during charging, the entire body of the charging terminal 107 similarly heats up. Such increase in temperature is detected by the temperature sensor 152. In various embodiments, the temperature sensor 152 is a thermistor. The temperature sensor 152 may include a resistance temperature detector.

The current sensor 154 monitors the current along the power transmission line. Monitoring the current allows the current sensor 154 to detect the high frequency spikes in the current along the power transmission line during the arc event. The current sensor 154 thus detects the arc event within the charging inlet assembly 100. In various embodiments, the current sensor 154 monitors for an arc noise signature to detect the arc event. In an exemplary embodiment, the current sensor 154 monitors for an arc noise signature to detect the arc event. For example, arc noise is generated by the arc event, such as in the radiofrequency range as a consequence of arc energy. The characteristic noise signature of the electrical arcing may be in a predetermined range, such as between 1 kHz-100 GHz. The characteristic noise signature of the electrical arcing may be in a more particular range, such as between 100-500 kHz. The current sensor 154 detects the stochastic energy, or noise signature, generated by the electrical arc. In an exemplary embodiment, the current sensor 154 may monitor the power transmission line of the charging inlet assembly 100 to detect the arc noise signature on the power transmission line corresponding to the arc event. The current sensor 154 may monitor the current along the charging terminals 107 and/or the power conductors 109.

In various embodiments, the charging controller 140 may include an arc fault circuit interrupter (AFCI) device to protect against electrical arcing, such as to shut down the charging circuit when an arc is detected. The current sensor 154 and/or the sensor antenna 158 monitors for the arc noise signature on the electrical circuit to detect the arc noise signature conducted on the power transmission line when the arc fault occurs. The charging controller 140 may include an internal processor in the ACFI device that distinguishes between normal operation and the hazardous arcing and will automatically open the circuit to reduce the risk of damage to the system.

In various embodiments, the current sensor 154 and/or the sensor antenna 158 is connected to other wiring or circuits to detect the arc noise signature. The current sensor 154 and/or the sensor antenna 158 may be located at the battery, such as at the battery distribution unit (BDU) rather than at the charging inlet housing. In other various embodiments, the current sensor 154 and/or the sensor antenna 158 includes a separate, dedicated arc detection wire, which may be routed from the charging terminal 107 to the circuit board 142 or routed to another component, such as the battery control module. The current sensor 154 may include a resistor-capacitor-inductor network or filter at the charging terminal 107 or at the circuit board 142 to enhance sensitivity to arc signature and minimize sensitivity to normal vehicle electrical noise.

In an exemplary embodiment, the current sensor 154 and/or the sensor antenna 158 noise is electrically coupled to the power transmission line at or near the cable connector 202 at the rear 212 of the charging terminal 107. The current sensor 154 and/or the sensor antenna 158 may be coupled to the cable connector 202 or to the conductor 109. In various embodiments, the current sensor 154 may include a current transformer around the power conductor 109 to monitor the electrical signature along the conductor 109. In other various embodiments, the current sensor 154 may include a Hall sensor adjacent to the conductor 109 or the cable connector 202 to monitor the electrical signature along the electrical circuit. In various embodiments, the current sensor 154 includes an induction coil to monitor the electrical signature along the electrical circuit. The induction coil may be positioned at or near the cable connector 202 or the conductor 109. The induction coil may be provided on a circuit board, such as the circuit board 142 or another circuit board, such as a circuit board for the temperature sensor system, In various embodiments, the induction coil is broadly tuned with a capacitor. The current sensor 154 may include isolation from the power circuit, such as from the conductors of the conductor 109 or the cable connector 202 to prevent damage to the current sensor 154. For example, the current transformers, the hall sensor and/or the induction coil may have electrical isolation from the conductors carrying charging current. Electrical isolation may be provided by suitable DC blocking capacitors to isolate the components from the charging current conductors.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. A vehicle charging system for an electric vehicle comprising:
a housing having a mating end for mating with a charging component for the electric vehicle, the housing including an internal cavity;
a charging terminal held by the housing in the internal cavity, the charging terminal including a mating end for mating with the charging component, the charging terminal being connected to a power conductor to form a power transmission line; and
a charging controller for controlling vehicle charging along the power transmission line, the charging controller including a charging sensor assembly coupled to the charging controller, the charging sensor assembly monitoring charging status of the vehicle charging system along the power transmission line and generating a charging output signal, the charging sensor assembly transmitting the charging output signal to the charging controller, the charging sensor assembly configured to detect an arc signature from an arc event and generate an arc output signal to the charging controller;
wherein, based on the arc output signal associated with the arc event, the charging controller generating a primary control output to perform a primary protective action including shutting down the charging operation; and
wherein, based on the arc output signal associated with the arc event, the charging controller generating a secondary control output to perform a secondary protective action.

2. The vehicle charging system of claim 1, wherein the secondary control output includes logging the arc event in a database.

3. The vehicle charging system of claim 2, wherein said logging the arc event includes sending arcing information to the database, the arcing information including the arc output signal from the arc sensor assembly.

4. The vehicle charging system of claim 1, wherein the secondary control output includes sending the secondary control output to the charging component to control the charging operation of the charging component.

5. The vehicle charging system of claim 1, wherein the secondary control output includes transmitting a warning signal to the operator of the vehicle, the warning signal being at least one or a visible signal, an audible signal, a tactile signal, and an olfactory signal.

6. The vehicle charging system of claim 1, further comprising a charging disconnecting device, the charging controller being operably coupled to the charging disconnecting device, the primary control output transmitted to the charging disconnecting device to shut down the charging operation.

7. The vehicle charging system of claim 6, wherein the charging disconnecting device includes one or a pyrofuse, a contactor, or a solid state relay configured to stop charging current on the power transmission line.

8. The vehicle charging system of claim 1, wherein the arc sensor assembly includes at least one of a temperature sensor, a current sensor, an optical sensor, and an arc detection antenna for detecting the arc signature.

9. The vehicle charging system of claim 1, wherein the charging controller includes an envelope detector defining a signal envelope encompassing the arc signature, the envelope detector detecting the arc event when the arc signature is in the signal envelope.

10. The vehicle charging system of claim 1, wherein the charging controller includes an anomaly detector configured to detect anomalous sensor readings from the arc sensor assembly, the anomaly detector treating the anomalous sensor readings as a positive arc signature to charging controller generates the primary control output and the secondary control output based on the anomalous sensor readings.

11. The vehicle charging system of claim 1, wherein the charging controller includes a digital signal processor configured to process the arc output signal, the digital signal processor configured to analyze the arc output signal to determine when the arc event is occurring and configured to generates the primary control output and the secondary control output based on the processed arc output signal.

12. The vehicle charging system of claim 1, wherein the charging controller is located in the internal cavity of the housing.

13. The vehicle charging system of claim 1, wherein the charging controller is located in a battery distribution unit of a battery system of the electric vehicle.

14. The vehicle charging system of claim 1, wherein the housing is a charging connector housing configured to be removably coupled to a charging inlet housing of the charging component of the vehicle, the charging terminal being a socket terminal configured to be mated with a pin terminal of the charging component to power the vehicle through the pin terminal.

15. The vehicle charging system of claim 1, wherein the housing is a charging inlet housing configured to be mounted to the vehicle and configured to receive a charging connector housing of the charging component, the charging terminal including a pin configured to be mated with a socket terminal of the charging component to receive power from the charging component.

16. A method of operating a vehicle charging system including a housing having a mating end for mating with a charging component for the electric vehicle and a charging terminal held by the housing including a mating end for mating with the charging component and being connected to a power conductor to form a power transmission line, the vehicle charging system including a charging controller for controlling vehicle charging along the power transmission line, the charging controller including a charging sensor assembly coupled to the charging controller; the method comprising:
monitoring charging status of the vehicle charging system along the power transmission line with the charging sensor assembly;
generating a charging output signal at the charging sensor assembly and transmitting the charging output signal to the charging controller, detecting an arc signature from an arc event along the power transmission line with the charging sensor assembly;
generating an arc output signal at the charging sensor assembly and transmitting the arc output signal to the charging controller;
generating a primary control output at the charging controller based on the arc output signal associated with the arc event to perform a primary protective action including shutting down the charging operation; and
generating a secondary control output at the charging controller based on the arc output signal associated with the arc event to perform a secondary protective action.

17. The method of claim 16, wherein said generating a secondary control output includes logging the arc event in a database.

18. The method of claim 16, wherein said generating a secondary control output includes sending the secondary control output to the charging component to control the charging operation of the charging component.

19. The method of claim 16, wherein said generating a secondary control output includes transmitting a warning signal to the operator of the vehicle, the warning signal being at least one or a visible signal, an audible signal, a tactile signal, and an olfactory signal.

20. The method of claim 16, wherein the vehicle charging system includes a charging disconnecting device operably coupled to the charging controller, said generating a primary control output includes transmitting the primary control output to the charging disconnecting device to shut down the charging operation.

21. The method of claim 16, wherein the charging controller includes an envelope detector defining a signal envelope encompassing the arc signature, said generating the arc output signal at the charging sensor assembly includes detecting the arc event with the envelope detector when the arc signature is in the signal envelope.

22. The method of claim 16, wherein the charging controller includes an anomaly detector, said generating the arc output signal at the charging sensor assembly includes detecting anomalous sensor readings from the arc sensor assembly and operating the anomaly detector to treat the anomalous sensor readings as a positive arc signature, said generating the primary control output and generating the secondary control output is based on the anomalous sensor readings.

23. The method of claim 16, wherein the charging controller includes a digital signal processor, the method further comprising processing the arc output signal with the digital signal processor and analyzing the arc output signal with the digital signal processor to determine when the arc event is occurring, said generating the primary control output and generating the secondary control output is based on the processed arc output signal.
